(19) United States
(12) Patent Application Publication
(10) Pub. No.: US 2019/0208329 A1
(43) Pub. Date: Jul. 4, 2019

(54) THIN AND FLEXIBLE LOUDSPEAKER USING ONE OR MORE PIEZOELECTRIC DIAPHRAGMS

(71) Applicant: Molex, LLC, Lisle, IL (US)

(72) Inventor: David Jonathan King, Eagan, MN (US)

(73) Assignee: Molex, LLC, Lisle, IL (US)

(21) Appl. No.: 16/189,710

(22) Filed: Nov. 13, 2018

Related U.S. Application Data
(60) Provisional application No. 62/585,509, filed on Nov. 13, 2017.

(51) Int. Cl. H04R 17/00; B06B 1/06; H01L 41/08; H01L 41/187

(52) U.S. Cl. CPC H04R 17/00; H01L 41/187; H01L 41/0805; B06B 1/0688

(57) ABSTRACT

A thin loudspeaker includes a substrate, a conductive trace on the substrate and forming a printed circuit, and one or more piezoelectric diaphragms fixedly attached to the substrate and electrically connected to the conductive traces.

### CROSS-REFERENCE TO RELATED APPLICATIONS

This application claims the benefit under 35 U.S.C. § 119(e) of the filing date of U.S. Provisional Patent Application No. 62/585,509, for “THIN AND FLEXIBLE LOUDSPEAKER USING MULTIPLE PIEZOELECTRIC DIAPHRAGMS” which was filed on Nov. 13, 2017, and which is incorporated here by reference.

### TECHNICAL FIELD

This disclosure relates to the field of loudspeakers, more specifically to a thin and flexible piezoelectric loudspeaker.

### DESCRIPTION OF RELATED ART

Printed electronics and flexible hybrid electronics (FHE) are emerging technologies that integrate additive printing technologies (e.g., screen printing, flexographic printing, inkjet printing, or other additive deposition techniques) with traditional packaged components. Benefits of printed electronics and FHE include, among others, flexibility and conformability. There is a need for integrating audio and recording capabilities with printed electronics and FHE for flexible and conformable applications that are also power efficient and capable of battery operation.

Current products in the market (e.g., audio greeting cards) typically use conventional magnet and cone loudspeaker technology and are thick (i.e., greater than 1 mm) and inflexible. Other speakers in the market are fabricated with piezoelectric ceramic materials, however, these speakers are also packaged in rigid materials, are thick (i.e., greater than 1 mm) and inflexible. FIG. 1A shows an image of a conventional magnetic-based speaker. FIG. 1B shows an image of a ceramic-based piezoelectric speaker. FIG. 2 shows a photograph of three piezoelectric diaphragms in the prior art. One aspect of commercially available ceramic-based piezoelectric speakers is that they require a rigid frame or rigid method for holding or supporting the piezoelectric material in order for the piezoelectric material to resonate properly.

Flexible polymer-based piezoelectric speakers (e.g., PVDF-based piezoelectric materials) have also been developed by university and industry groups. While these speakers are thin (e.g., generally between 10 μm and 250 μm) and flexible, they are very inefficient and require significant driving voltage (e.g., greater than +/−60 V to up to +/−150 V) to achieve acceptable sound pressure levels (SPLs) and are therefore not useful for products requiring mobility and battery operation. In addition, the sound fidelity of these PVDF-based speakers is generally of poor quality.

### SUMMARY

In a first aspect, a thin loudspeaker includes a substrate, a conductive trace on the substrate and forming a printed circuit, and one or more piezoelectric diaphragms fixedly attached to the substrate and electrically connected to the conductive traces.

In a second aspect, a flexible audio module includes a substrate, a conductive trace on the substrate and forming a printed circuit, one or more piezoelectric diaphragms fixedly attached to the substrate and electrically connected to the conductive traces, and an electrical circuit provided on the substrate. The electrical circuit includes an audio amplifier, a microcontroller, a wireless communication chip, an antenna, and a power supply.

In a third aspect, a method includes laying a conductive trace on a substrate to form a printed circuit, fixedly attaching one or more piezoelectric diaphragms to the substrate, and electrically connecting the one or more piezoelectric diaphragms to the conductive trace.

### BRIEF DESCRIPTION OF THE DRAWINGS

The present application is illustrated by way of example and not limited in the accompanying figures in which like reference numerals indicate similar elements and in which:

FIG. 1A is an example conventional magnetic-based speaker in the prior art;

FIG. 1B is an example a ceramic-based piezoelectric speaker in the prior art;

FIG. 2 is an example of three piezoelectric diaphragms in the prior art;

FIG. 3A is a cross-sectional diagram of an example monomorphic piezoelectric diaphragm;

FIG. 3B is a top-down diagram of the example monomorphic piezoelectric diaphragm of FIG. 3A;

FIG. 3C is a cross-sectional diagram of an example bimorphic piezoelectric diaphragm;

FIG. 4 is a diagram of a first example thin and flexible loudspeaker;

FIG. 5 is a diagram of a second example thin and flexible loudspeaker;

FIG. 6 is a diagram of a third example thin and flexible loudspeaker;

FIG. 7 is a diagram of a fourth example thin and flexible loudspeaker; and

FIG. 8 is a SPL Frequency Response plot of an example thin and flexible loudspeaker.

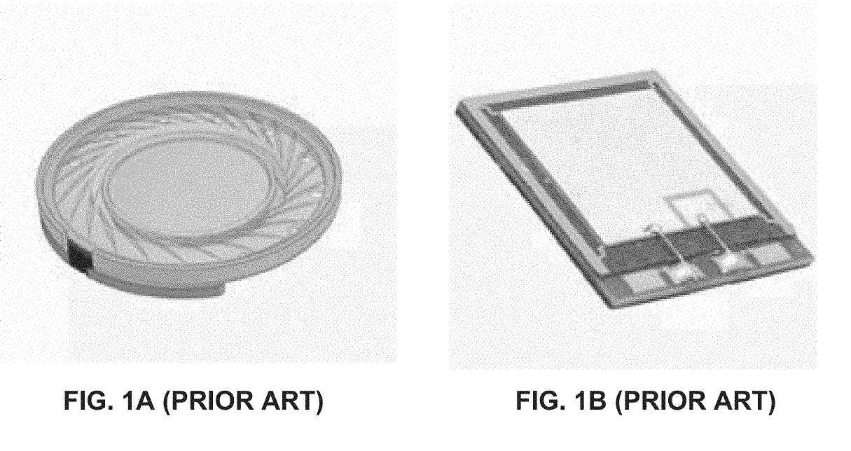

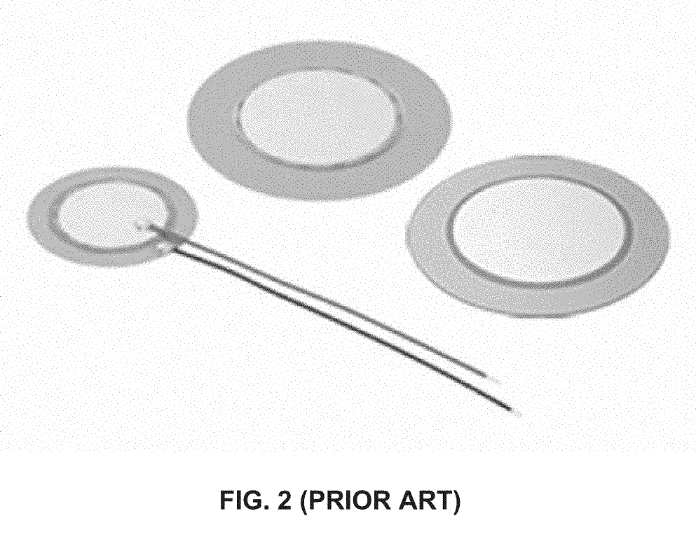

### DETAILED DESCRIPTION

The detailed description that follows describes exemplary embodiments and the features disclosed are not intended to be limited to the expressly disclosed combination(s). Therefore, unless otherwise noted, features disclosed herein may be combined together to form additional combinations that were not otherwise shown for purposes of brevity.

As used herein, the term piezoelectric diaphragm is defined as a device that uses the piezoelectric effect to generate an audible tone or sound. As used herein, the term piezoelectric diaphragm can also be described as a piezoelectric bender, and/or a piezoelectric buzzer, and/or a piezoelectric beeper, and/or a piezoelectric speaker, piezoelectric transducer, and/or a piezoelectric ceramic transducer, and/or the like. As used here, a monomorph piezoelectric diaphragm includes a single piezoelectric layer, whereas a bimorph piezoelectric diaphragm includes two piezoelectric layers.

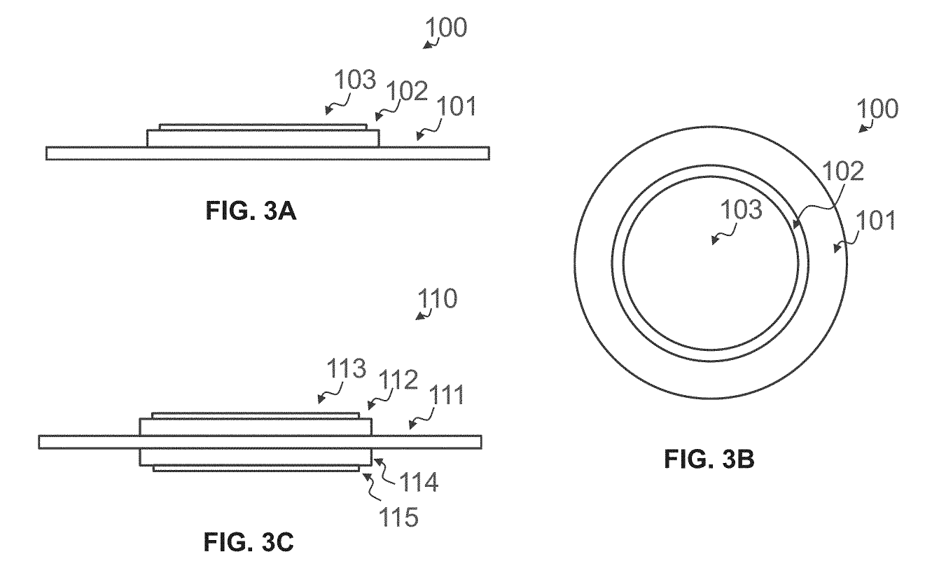

FIG. 3A shows a cross-sectional diagram of monomorph piezoelectric diaphragm 100 and a FIG. 3B shows a top-down diagram of monomorph piezoelectric diaphragm 100. Piezoelectric diaphragm 100 includes metallic diaphragm 101, piezoelectric ceramic material layer 102 fixedly attached to metallic diaphragm 101, and conductive layer 103 electrically connected to the piezoelectric ceramic material layer 102. In some embodiments, monomorph piezoelectric diaphragm 100 has a thickness that is less than 1 mm. In other embodiments, the monomorph piezoelectric diaphragm 100 has a thickness that is less than 0.5 mm, or less than 0.4 mm, or less than 0.3 mm, or less than 0.2 mm. Other constructions of monomorphic piezoelectric diaphragms are commercially available and, in some embodiments, are included in the thin and flexible loudspeaker of the present invention.

FIG. 3C shows a cross-sectional diagram of bimorph piezoelectric diaphragm 110. Bimorph piezoelectric diaphragm 110 includes metallic diaphragm 111 having a first side and a second side, a first piezoelectric ceramic material layer 112 fixedly attached to the first side of metallic diaphragm 111, conductive layer 113 electrically connected to the first piezoelectric ceramic material layer 112, a second piezoelectric ceramic material layer 114 fixedly attached to a second side of metallic diaphragm 111, conductive layer 115 electrically connected to the second piezoelectric ceramic material layer 114. In some embodiments, bimorph piezoelectric diaphragm 110 has a thickness that is less than 1.5 mm. In other embodiments, the piezoelectric diaphragm 110 has a thickness that is less than 1.25 mm, less than 1.0 mm, less than 0.75 mm, less than 0.5 mm, or less than 0.4 mm, or less than 0.3 mm, or less than 0.2 mm. Other constructions of bimorph piezoelectric diaphragms are commercially available and, in some embodiments, are included in the thin and flexible loudspeaker of the present invention.

Piezoelectric diaphragms convert electrical voltage to audible sound with a resonant frequency that is determined by the general size and shape of the diaphragm. While piezoelectric diaphragms generate sound, their frequency response is not generally flat across the audio spectrum and therefore piezoelectric diaphragms are not ideal for recreating audio recordings (e.g., music, spoken word, radio, and the like) with good fidelity or intelligibility. This is especially true for the lower audible frequency range (e.g., 100 Hz to 1,000 Hz). Piezoelectric diaphragms are typically used to produce alert tones for alarms, buzzers, and warnings signals with the audible tone selected according to the resonant frequency of the piezoelectric diaphragm to achieve the loudest SPL and, therefore, alert tone. Depending on the total thickness of the piezoelectric diaphragm they can be semi-flexible to flexible.

The present invention provides, a thin and flexible loudspeaker that includes one or more piezoelectric diaphragms and methods for fabricating such thin and flexible loudspeakers.

In some embodiments, two or more piezoelectric diaphragms are provided to construct a loudspeaker having a smooth and level audio frequency response and acceptable audio volume level. In some such embodiments, the two or more piezoelectric diaphragms are substantially similar, e.g., the two or more piezoelectric diaphragms have metallic diaphragms that are substantially the same diameter and have piezoelectric ceramic layers that are substantially the same diameter. In other embodiments, the two or more piezoelectric diaphragms are different, e.g., the two or more piezoelectric diaphragms have metallic diaphragms that are not the same diameter and have piezoelectric ceramic layers that are not the same diameter. In some embodiments, the diameter of the metallic layer and the piezoelectric ceramic layer for each one of the two or more piezoelectric diaphragms are selected to provide a smooth and level audio frequency response and acceptable sound pressure level (i.e., SPL).

In some embodiments, a single bimorph piezoelectric diaphragm is provided to construct a loudspeaker with a smooth and level audio frequency response and acceptable audio volume level. In some such embodiments, the single bimorph piezoelectric diaphragm includes a first piezoelectric ceramic layer that has substantially the same diameter as the second piezoelectric ceramic layer. In other such embodiments, the first piezoelectric ceramic layer has a diameter that is substantially different than the diameter of the second piezoelectric ceramic layer. In some embodiments, the diameter of the first and the second piezoelectric ceramic layers are selected to provide a smooth and level audio frequency response and acceptable SPL.

In some embodiments, the loudspeaker of the present invention is both a vibrating transducer and a dipole. In some embodiments, the loudspeaker of the present invention includes, one or more bimorph piezoelectric bimorph diaphragms, monomorph piezoelectric diaphragms, or combinations thereof.

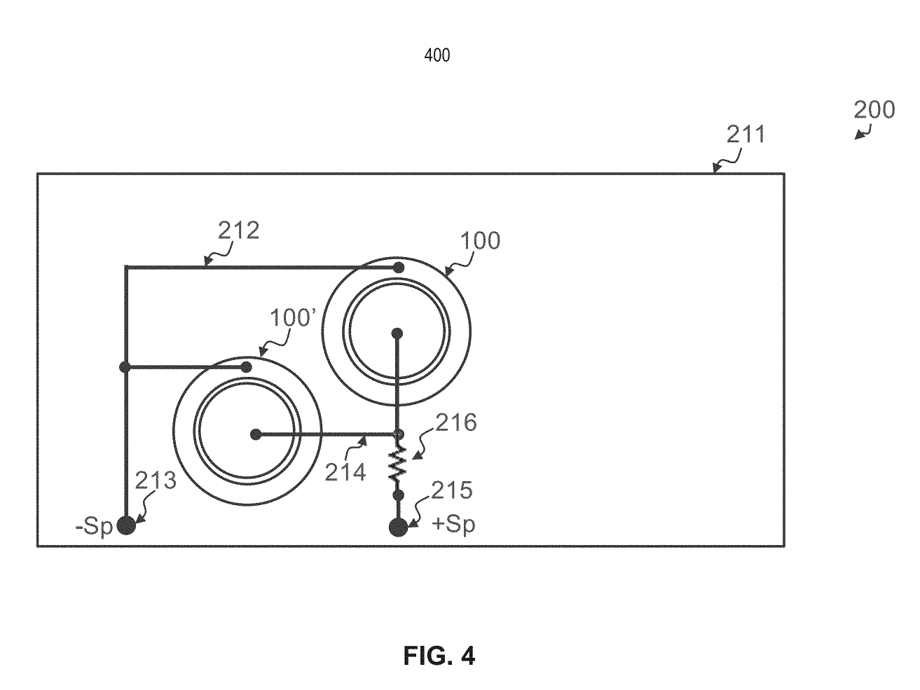

In some embodiments, as described below and shown in FIG. 4, thin and flexible loudspeaker 200 of the present invention includes a substrate 211 with a top surface and a bottom surface, a plurality of piezoelectric diaphragms 100 and 100′ fixedly attached to the top surface of the substrate, conductive traces 212 and 214 that electrically connect to the metallic diaphragm and the conductive layer, respectively, of the piezoelectric diaphragms 100 and 100′. Loudspeaker 200 also includes electrical connections 213 and 214 that are electrically connected to a negative driving audio signal and a positive driving audio signal, respectively, that are output by an audio amplifier. In some embodiments, loudspeaker 200 further includes a resistor 216 that is used to determine the upper cutoff frequency of the driving audio signal provided by an audio amplifier to the loudspeaker 200.

In some embodiments, piezoelectric diaphragms 100 and 100′ are selected such that constructive and/or destructive interference of the two piezoelectric diaphragms and improve the audible portion of the frequency response curve. In some embodiments, the SPL of the audible portion is increased and the curve is shifted toward lower frequencies to improve the audio output and intelligibility. In some embodiments, piezoelectric diaphragms 100 and 100′ are selected to have the same resonant frequency, whereas, in other embodiments, piezoelectric diaphragms 100 and 100′ are selected to have difference resonant frequencies. In some embodiments, piezoelectric diaphragms 100 and 100′ have resonant frequencies that are selected from the range of frequencies of 400 Hz to 1,200 Hz. In other embodiments, piezoelectric diaphragms 100 and 100′ have resonant frequencies that are selected from the range of frequencies of 600 Hz to 1000 Hz. In some embodiments, the low frequency response of loudspeaker 200 is improved (i.e., increased) by selecting piezoelectric diaphragms with a resonant frequency that is lower than the dipole cutoff.

In some embodiments, conductive traces 212 and 214 are selectively printed or otherwise deposited to form the circuit traces by any of a variety of printing or additive deposition methodologies, including, for example, any form of gravure, flatbed screen, flexography, lithography, screen, rotary screen, digital printing, inkjet printing, aerosol jet printing, 3-D printing, and like print methods, or combinations thereof.

In other embodiments, conductive traces 212 and 214 are provided by traditional PCB fabrication technology. In yet other embodiments, conductive traces 212 and 214 are provided by conductive wires. In some embodiments, conductive traces 212 and 214 can comprise a printable or otherwise selectively deposited conductive material containing metallic particles such as, for example, but not limited to, silver, platinum, palladium, copper, nickel, gold, or aluminum or carbon or conductive polymer, or some combination thereof. Conductive traces 212 and 214 can be flakes, fine particulates, or nano-particulates, or combinations thereof, in some embodiments. Conductive traces 212 and 214 can be in the form of a printable conductive ink, toner, or other coating. In some embodiments, electrically functional electronic inks are available from Henkel Corporation or DuPont Inc., for example. Conductive traces 212 and 214 can also be formed by other means known to those having skill in the art.

In some embodiments, substrate 211 has a thickness of 3 mil. In other embodiments, substrate 211 has a thickness that is less than 10 mil, and more specifically, a thickness that is less than 5 mil. In some embodiments, substrate 211 has a size that is approximately 3 inches by 6 inches. In other embodiments, substrate 211 has a size that is approximately 6 inches by 6 inches, or 8.5 inches by 11 inches, or 4.25 inches by 5.5 inches. In some embodiments, substrate 211 has a rectangular shape, or a square shape, or a round shape, or an odd and/or irregular shape. In some embodiments, the size and shape of substrate 211 is selected to reduce the low frequency response of the dipole.

In some embodiments, substrate 211 includes one or more of any of a number of flexible materials, such as polymeric materials including but not limited to, polyethylene terephthalate film (PET), polyethylene naphthalate (PEN), polyimide foil (PI), polypropylene, polyethylene, polystyrene, polycarbonate, polyether ether ketone (PEEK), or any of a variety of polymer films or combinations thereof. In an alternative embodiment, substrate 211 is semi-flexible and comprises thin glass, wood, metal, PVC, silicon, epoxy resin, polycarbonate, or any of a variety of semi-flexible materials or combinations thereof. In yet another embodiment, substrate 211 includes a combination of one or more flexible materials described herein and one or more semi-flexible materials described herein. In yet other embodiments, substrate 211 includes rigid portions in combination with flexible or semi-flexible materials described herein.

Those having ordinary skill in the art will recognize that many types of audio amplifiers can be used for providing the driving audio signals necessary for driving the piezoelectric diaphragms 100 and 100′ of loudspeaker 200.

In some embodiments, loudspeaker 200 is thin and flexible such that it can travel through a media transport path of a printer (i.e., the path a piece of paper or other media travels through the printer during a print cycle) in order to have graphics printed on one and/or both sides of loudspeaker 200. In some embodiments, loudspeaker 200 can travel through the media transport path of at least one of the following printer types, including a laser printer, an inkjet printer, or the like.

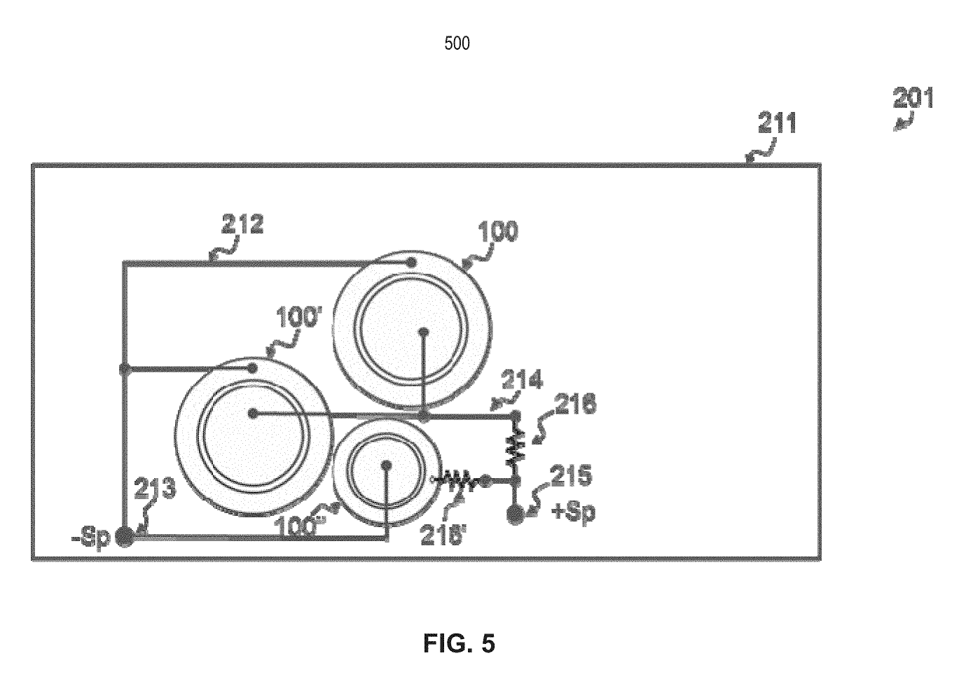

FIG. 5 provides a diagram of thin and flexible loudspeaker 201, according to some embodiments of the present invention. In some embodiments, loudspeaker 201 is substantially similar to loudspeaker 200 described above and in FIG. 4, except that loudspeaker 201 further includes piezoelectric diaphragm 100″ and resistor 216′. In some embodiments, piezoelectric diaphragm 100″ is connected to the positive driving signal connector 215 and the negative driving audio signal connector 213 such that piezoelectric diaphragm 100″ is driven out of phase with both piezoelectric diaphragms 100 and 100′. In other embodiments, piezoelectric diaphragm 100″ is driven in phase with piezoelectric diaphragms 100 and 100′.

In some embodiments, the resonant frequency of piezoelectric diaphragm 100″ is selected such that, when driven out of phase with diaphragms 100 and 100′, undesirable higher frequency response peaks are reduced. In other embodiments, the resonant frequency of piezoelectric diaphragm 100″ is selected such that, when driven in phase with diaphragms 100 and 100′, portions of the frequency response that are low will be increased to achieve a smooth frequency response across the audible spectrum. In some embodiments, piezoelectric diaphragm 100″ is added to provide minor adjustments to the frequency response to improve SPL and intelligibility.

In some embodiments, the piezoelectric diaphragm 100″ has a resonance frequency in the range of about 1,000 Hz to about 5,000 Hz, or more specifically in a range of about 1,500 Hz to about 3,500 Hz. In other embodiments, the piezoelectric diaphragm 100″ has a resonance frequency in the range of about 2,000 Hz to about 3,000 Hz.

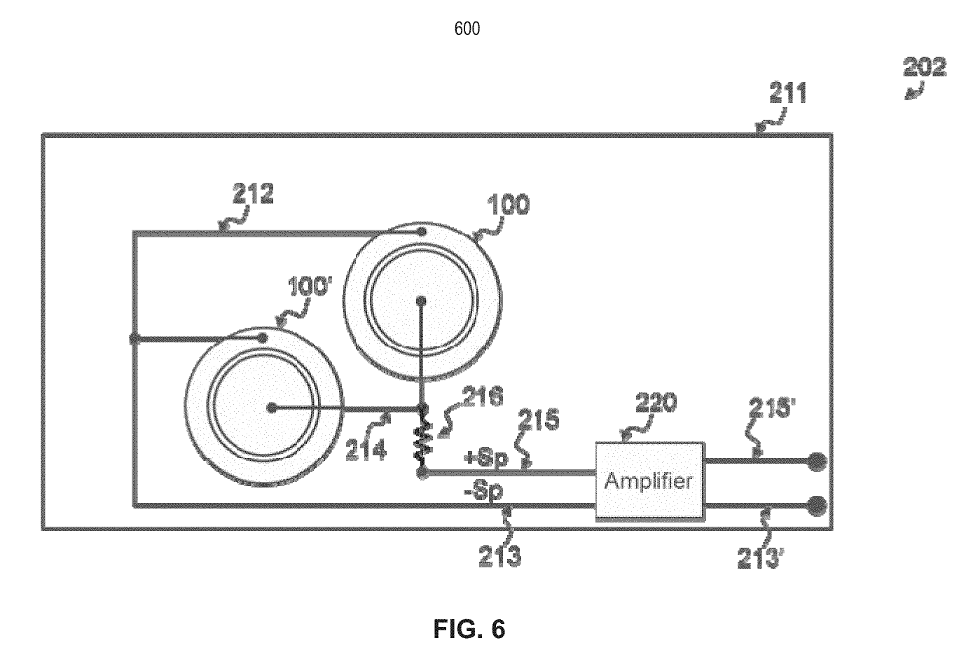

FIG. 6 provides a diagram of thin and flexible loudspeaker 202, according to some embodiments of the present invention. In some embodiments, loudspeaker 202 is substantially similar to loudspeaker 200 described above and in FIG. 4, except that loudspeaker 202 further includes an integrated audio amplifier 220 that is mechanically attached to substrate 211 and electrically attached to conductive traces 212 and 214. In some embodiments, integrated audio amplifier has two inputs (audio input 213′ and 215′) that is amplified by audio amplifier 220 and the amplified signals (amplified audio signal 213 and amplified audio signal 215) drive the plurality of piezoelectric diaphragms 100 and 100′. In some embodiments, the audio input signals (213′ and 215′) are provided by an audio device that is separate from, but electrically connected to the loudspeaker 202.

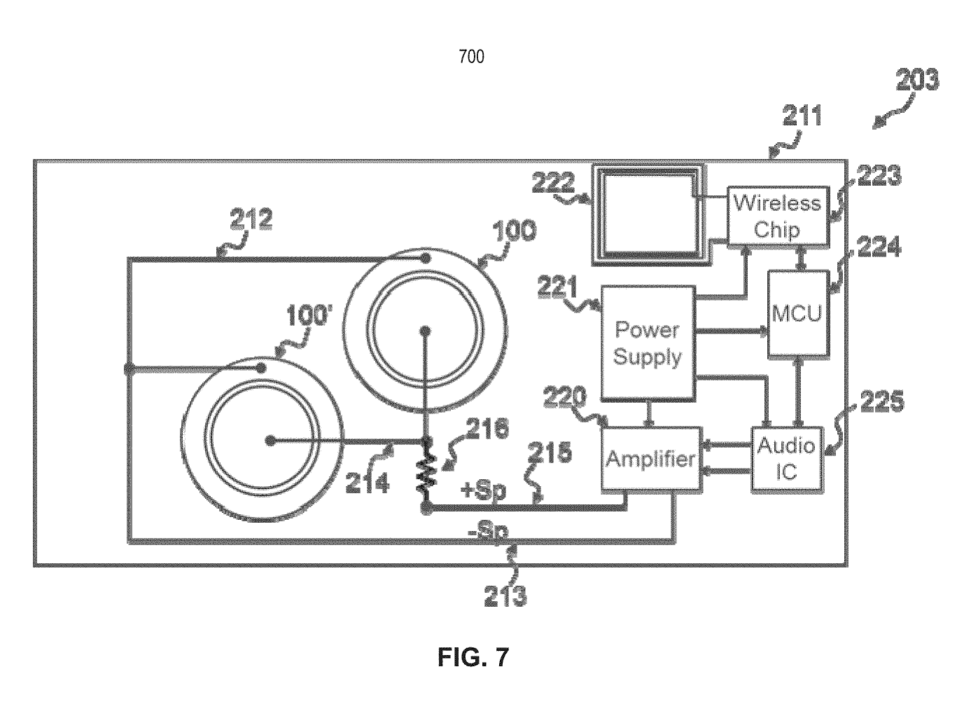

FIG. 7 Diagram of thin and flexible loudspeaker integrated module 203, according to some embodiments of the present invention. In some embodiments, loudspeaker module 203 is substantially similar to loudspeaker 202 described above and in FIG. 6, except that loudspeaker module 203 further includes an integrated electrical circuit electrically connected to the plurality of benders (100 and 100′) and including an audio amplifier 220 electrically connected to receive audio signals from audio IC 225, microcontroller 224 electrically connected to receive and transmit information to and/or from audio IC 225, wireless chip 223 electrically connected to receive and transmit information to and/or from wireless chip 223, antenna 222 configured to receive and transmit information wirelessly and electrically connected to provide and/or receive information to and/or from wireless chip 223. In some embodiments, loudspeaker 203 further includes a power supply 221 that is configured to provide power to audio amplifier 220, wireless chip 223, MCU 224, and audio IC 225. In some embodiments, power supply 221 includes one or more battery cells. In other embodiments, power supply 221 includes a photovoltaic cell, or other renewable energy source.

In some embodiments, one or more of the piezoelectric diaphragms (e.g., diaphragm 100, and/or, diaphragm 100′, and/or diaphragm 100″) provides tactile haptic feedback. For example, piezoelectric diaphragm 100 can be used to play audio when diaphragm 100 is driven by frequencies in the audio spectrum and can be used to provide tactile haptic feedback by driving the diaphragm 100 at a frequency that provides a good tactile response (e.g., a frequency below a few hundred Hertz). In some such embodiments, the piezoelectric diaphragm can be used as an audio transducer, or to provide tactile feedback, or both. Tactile haptic feedback is feedback from an action (e.g., activating a switch) on flexible loudspeaker integrated module 203 that is reproduced as a physical sensation, such as touch.

In some embodiments, one or more of the piezoelectric diaphragms (e.g., diaphragm 100, and/or, diaphragm 100′, and/or diaphragm 100″) is used as a sensor to vibration, pressure, force, and the like. In some such embodiments, the piezoelectric diaphragm can be used as an audio transducer, or as a sensor, or to provide tactile feedback, or combinations thereof.

In some embodiments, the loudspeaker integrated module 203 of the present invention further includes a method for activating and/or triggering an action. For example, in some embodiments, a switch is provided to activate playback an audio message that is stored on Audio IC 225. In another embodiment, a sensor is provided to trigger the MCU 224 to “wake up” and instruct the Wireless Chip 223 to begin broadcasting information about the sensor state to a gateway receiver. In some embodiments, the sensor could be a temperature and humidity sensor. Those with skill in the art will recognize that many additional activation methods exist and can be integrated into the loudspeaker integrated module 203.

In some embodiments, the loudspeaker of the present invention includes an electrical circuit comprising one or more conventional packaged components, such as resistors, capacitors, inductors, microcontrollers, memory chips, wireless connectivity chips, and the like.

In some embodiments, integrated wireless communication chip 223 includes the capability for one or more wireless communication protocol, including RFID, NFC, Bluetooth, LoRa, SigFox, ZigBee, Wi-Fi, Wi-MAX, or other useful wireless protocol.

In some embodiments, integrated antenna 222 is formed from a conductive trace using any of the additive techniques described herein. In other embodiments, integrated antenna 222 is formed from wire coils. In yet other embodiments, integrated antenna 222 is formed using photolithographic techniques and wet or dry etching.

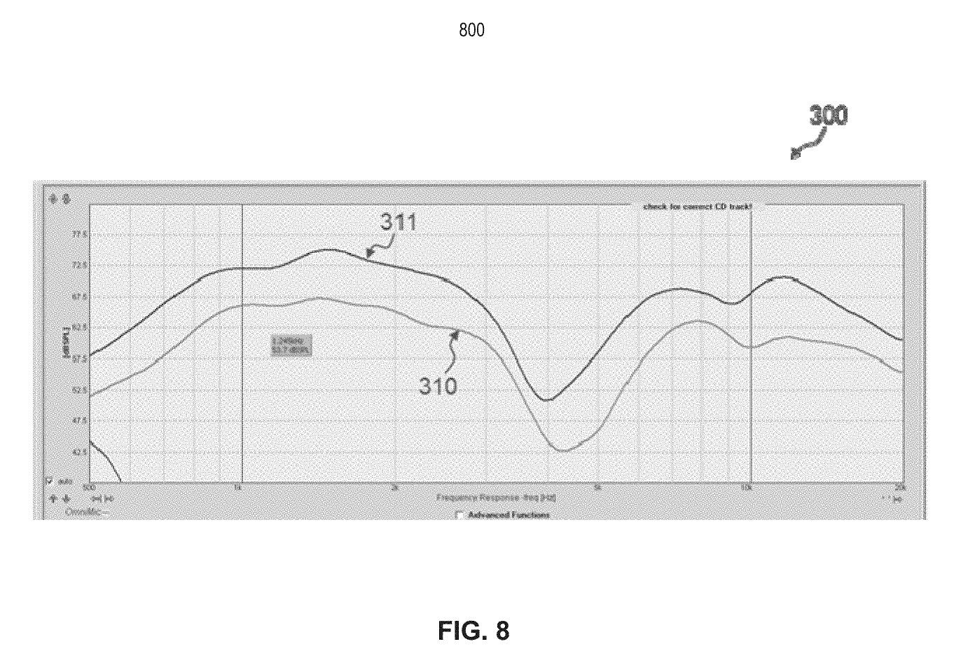

FIG. 8 shows SPL Frequency Response plot 300 of a thin and flexible loudspeaker, according to some embodiments of the present invention. Trace 310 is a frequency response generated by loudspeaker having only a single piezoelectric diaphragm. Trace 311 is a frequency response generated by a loudspeaker having two piezoelectric diaphragms according to the present invention. As shown in FIG. 8, the loudspeaker of the present invention provides a frequency response curve 311 that has a higher SPL that is shifted towards lower frequencies, as compared to a single piezoelectric diaphragm loudspeaker.

In some embodiments, the loudspeaker of the present invention does not require a rigid frame or rigid method for holding or supporting the piezoelectric diaphragm.

In some embodiments, the loudspeaker of the present invention further includes resistors are added in series with one or more of the piezoelectric diaphragms to induce a phase shift for smoothing the frequency response.

In some embodiments, the loudspeaker of the present invention further includes reactive components (e.g., capacitors or inductors) added in series or parallel to induce a phase shift for smoothing the frequency response.

In some embodiments, the shape of the piezoelectric diaphragm includes at least one of the following shapes, including circular, rectangular, square, oval, or other shape useful for improving the frequency response of the loudspeaker, particularly in the audible frequency range.

In some embodiments, the thin and flexible loudspeaker of the present invention can bend around a mandrel with a radius of curvature of less than 2 inches. In other embodiments, the loudspeaker can bend around a mandrel of less than 1.5 inches, or less than 1.0 inches, or less than 0.75 inches, or less than 0.5 inches, or less than 0.25 inches.

In some embodiments, the loudspeaker of the present invention includes one or more sensors, including thermistors, temperature, humidity, acceleration, and or the like.

In some embodiments, the loudspeaker of the present invention includes packaged components and devices are attached to the conductive traces using one or more of the following attachment techniques including, solder, low temperature solder, conductive epoxy, anisotropic conductive adhesive, and the like.

In some embodiments, the loudspeaker of the present invention includes conductive traces on the top surface and the bottom surface of the substrate, wherein the top and bottom conductive traces are electrically connected through vias formed using one or more of the following methods, including lasered vias, poke-through via, and the like.

It will be appreciated that the foregoing description provides examples of the disclosed system and technique. However, it is contemplated that other implementations of the disclosure may differ in detail from the foregoing examples. All references to the disclosure or examples thereof are intended to reference the particular example being discussed at that point and are not intended to imply any limitation as to the scope of the disclosure more generally. All language of distinction and disparagement with respect to certain features is intended to indicate a lack of preference for those features, but not to exclude such from the scope of the disclosure entirely unless otherwise indicated.

Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context.

Accordingly, this disclosure includes all modifications and equivalents of the subject matter recited in the claims appended hereto as permitted by applicable law. Moreover, any combination of the above-described elements in all possible variations thereof is encompassed by the disclosure unless otherwise indicated herein or otherwise clearly contradicted by context.

1. A thin loudspeaker, comprising:
a substrate;
a conductive trace on the substrate and forming a printed circuit; and
one or more piezoelectric diaphragms fixedly attached to the substrate and electrically connected to the conductive traces.

2. The flexible loudspeaker according to claim 1, wherein the substrate is comprising a flexible material.

3. The flexible loudspeaker according to claim 1, wherein the one or more piezoelectric diaphragms comprises a monomorph piezoelectric diaphragm.

4. The flexible loudspeaker according to claim 1, wherein the one or more piezoelectric diaphragms comprises a first monomorph piezoelectric diaphragm having a first diameter and a second monomorph piezoelectric diaphragm having a second diameter, wherein the first diameter is greater than the second diameter.

5. The flexible loudspeaker according to claim 1, wherein the one or more piezoelectric diaphragms comprises a single bimorph piezoelectric diaphragm.

6. The flexible loudspeaker according to claim 5, wherein the single bimorph piezoelectric diaphragm comprises:
a metallic layer having a first side and a second side;
a first piezoelectric ceramic layer fixedly attached to the first side of the metallic layer and having a first diameter; and
a second piezoelectric ceramic layer fixedly attached to the second side of the metallic layer and having a second diameter;

7. The flexible loudspeaker according to claim 6, wherein the first diameter is greater than the second diameter.

8. The flexible loudspeaker according to claim 1, wherein the one or more piezoelectric diaphragms comprises a combination of monomorph piezoelectric diaphragms and bimorph piezoelectric diaphragms.

9. The flexible loudspeaker according to claim 1, wherein the one or more piezoelectric diaphragms comprises a first piezoelectric diaphragm having a first diameter and a second piezoelectric diaphragm having a second diameter, wherein the first diameter is greater than the second diameter.

10. The flexible loudspeaker according to claim 1, wherein the conductive trace is formed from metallic flakes, metallic fine particulates, metallic nano-particulates, or combinations thereof.

11. The flexible loudspeaker according to claim 10, wherein the additive fabrication method is at least one of gravure, flatbed screen, flexography, lithography, screen, rotary screen, digital printing, inkjet printing, aerosol jet printing, 3-D printing, like print methods, or combinations thereof.

12. The flexible loudspeaker according to claim 1, wherein the conductive trace is formed using an additive fabrication method.

13. The flexible loudspeaker according to claim 1, wherein the substrate is formed from a polymeric material.

14. The flexible loudspeaker according to claim 1, further comprising a resistor, electrically connected between the conductive trace and the one or more piezoelectric diagrams, and used to select an upper cutoff frequency of a driving audio signal.

15. The flexible loudspeaker according to claim 1, further comprising an audio amplifier fixedly attached to the substrate and electrically connected between the conductive trace and the one or more piezoelectric diaphragms to amplify an audio signal provided to the one or more piezoelectric diaphragms.

16. The flexible loudspeaker according to claim 1, further comprising a pair of electrical connectors for a negative driving audio signal and a positive driving audio signal.

17. A flexible audio module, comprising:
a substrate;
a conductive trace on the substrate and forming a printed circuit;
one or more piezoelectric diaphragms fixedly attached to the substrate and electrically connected to the conductive traces; and
an electrical circuit provided on the substrate, wherein the electrical circuit comprises:
an audio amplifier;
a microcontroller;
a wireless communication chip;
an antenna; and
a power supply.

18. The flexible audio module of claim 17, wherein the power supply comprises a photovoltaic cell.

19. A method, comprising:
laying a conductive trace on a substrate to form a printed circuit;
fixedly attaching one or more piezoelectric diaphragms to the substrate; and
electrically connecting the one or more piezoelectric diaphragms to the conductive trace.

20. The method of claim 19, wherein the one or more piezoelectric diaphragms is configured for at least one of vibration sensing, force sensing, or providing tactile feedback.
